(19) United States
(12) Patent Application Publication
(10) Pub. No.: US 2024/0012618 A1
(43) Pub. Date: Jan. 11, 2024

(54) DIFFERENTIAL QUANTUM NOISE SOURCE

(71) Applicant: Quintessence Labs Pty Ltd., Canberra Airport (AU)

(72) Inventors: Andrew Lance, Canberra (AU); Alvin Labios, Canberra Airport (AU)

(73) Assignee: Quintessence Labs Pty Ltd., Canberra Airport (AU)

(21) Appl. No.: 18/117,994

(22) Filed: Mar. 6, 2023

Related U.S. Application Data
(60) Provisional application No. 63/318,324, filed on Mar. 9, 2022.

(51) Int. Cl. G06F 7/58

(52) U.S. Cl. CPC G06F 7/588

(57) ABSTRACT

A system for generating a quantum random number stream may include a first noise source. The system may also include a first bias device, configured to bias the first noise source such that the first noise source generates a first noise, and a second noise source and a second bias device, configured to bias the second noise source such that the second noise source generates a second noise. The system may also include a first amplifier with a first input channel and a second input channel configured to receive the first noise and the second noise, respectively. The amplifier may use a difference between the first and second noises to generate a first amplified analog signal for output. The system may also include an analog-to-digital converter device configured to convert an amplified analog signal to the quantum random number stream then output the quantum random number stream.

### CROSS-REFERENCES TO RELATED APPLICATIONS

This application claims the benefit of U.S. Provisional Application No. 63/318,324, filed Mar. 9, 2022, the disclosure of which is incorporated herein by reference.

### BACKGROUND

Random number generation may be used for a variety of security-related applications. Some techniques for generating random numbers may be prone to error or vulnerable to attack. Entropy associated with a random number generator may also be limited.

### BRIEF SUMMARY

A system for generating a quantum random number stream may include a first quantum noise source. The system may also include a first bias device, configured to bias the first quantum noise source such that the first quantum noise source generates a first noise. The system may also include a second quantum noise source and a second bias device, configured to bias the second quantum noise source such that the second quantum noise source generates a second noise. The system may also include a first amplifier with a first input channel configured to receive the first noise from the first quantum noise source, and a second input channel configured to receive the second noise from the second quantum noise source. The amplifier may use a difference between the first noise and the second noise to generate a first amplified analog signal for output. The system may also include an analog-to-digital converter device configured to convert an amplified analog signal to the quantum random number stream. The system may output the quantum random number stream.

In some embodiments, at least one of the first noise source or the second noise source may include a metal-oxide semiconductor field-effect transistor, a junction field-effect transistor, or a tunnel diode. The first noise source and the second noise source may include a same device or may include different devices.

In some embodiments, a corrective feedback signal may be generated at least in part based on the amplified analog signal and provided to at least one of the differential amplifier, the first bias device, or the second bias device. The corrective feedback signal may be generated by at least one of an analog accumulator or an analog integrator.

In some embodiments, the system may include a third quantum noise source and a third bias device, configured to bias the third quantum noise source such that the third quantum noise source generates a third noise. The system may also include a fourth quantum noise source and a fourth bias device, configured to bias the fourth quantum noise source such that the fourth quantum noise source generates a fourth noise. The system may also include a second amplifier, comprising a third input channel configured to receive the third noise and a fourth input channel configured to receive the fourth noise. The amplifier may use a difference between the third noise and the fourth noise to generate a second amplified analog signal for output. The system may also include a third amplifier. The third amplifier may receive the first amplified analog signal and the second amplified analog signal and combine the first amplified analog signal and the second amplified analog signal to generate a combined analog signal for output. In some embodiments, the combined analog signal may be the amplified analog signal, and the analog-to-digital converter device may convert the amplified analog signal to the quantum random number stream and output the quantum random number stream.

In some embodiments, a portion of the quantum random number stream may be used to generate a quantum random number. The quantum random number may be accessed by a field programmable gate array configured to modify the quantum random number by at least one of a hash function or a folding technique, prior to being output for a user device.

A method of generating a quantum random number may include providing, by a first noise source, a first noise to an amplifier. The method may also include providing, by a second noise source, a second noise to the amplifier. The method may also include combining, by the amplifier, the first noise and the second noise to generate an amplified analog signal for output. The method may also include converting, by an analog-to-digital converter (ADC) device, the amplified analog signal into a quantum random number stream. The method may also include outputting, by the ADC device, the quantum random number stream.

In some embodiments, the method may include providing, by a first bias device, a first bias to the first noise source such that the first noise source generates the first noise. The method may also include providing, by a second bias device, a second bias to the second noise source such that the second quantum noise source generates the second noise. The first bias and the second bias may provide a voltage bias or a current bias to the first noise source and the second noise source, respectively. In some embodiments, the first bias may provide a voltage bias to the first noise source and the second bias may provide a current bias to the second noise source.

In some embodiments, the method may include providing a corrective feedback signal to at least one of the first bias device or the second bias device. The method may also include sampling a portion of the quantum random number stream to generate a quantum random number and providing the quantum random number to a user device.

A system for generating a quantum random number stream may include a first quantum noise source. The system may also include a first bias device, configured to bias the first quantum noise source such that the first quantum noise source generates a first noise. The system may also a second quantum noise source and a second bias device, configured to bias the second quantum noise source such that the second quantum noise source generates a second noise. The system may also include a first differential buffer with a first input channel configured to receive the first noise from the first quantum noise source. The first differential buffer may also include a second input channel configured to receive a first corrective feedback signal. The first differential buffer may combine the first noise and the first corrective feedback signal to generate a first corrected noise. The system may also include a second differential buffer with a third input channel configured to receive the second noise from the second quantum noise source. The second differential buffer may include a fourth input channel configured to receive a second corrective feedback signal. The second differential buffer may combine the second noise and the second corrective feedback signal to generate a second corrected noise. The system may also include a differential amplifier that uses a difference between the first corrected noise and the second corrected noise to generate an amplified analog signal for output. The system may also include an analog-to-digital converter (adc) device configured to convert the amplified analog signal to a quantum random number stream and output the quantum random number stream.

In some embodiments, at least one of the first quantum noise source or the second quantum noise source may include a metal-oxide semiconductor field-effect transistor, a junction field-effect transistor, or a tunnel diode. In some embodiments, the first corrective feedback signal and the second corrective feedback signal may be the same corrective feedback signal. The first corrective feedback signal and the second corrective feedback signal may be generated by at least one of an analog accumulator or an analog integrator.

### BRIEF DESCRIPTION OF THE DRAWINGS

FIG. 1 illustrates a simplified diagram of a quantum random number generator with an unwanted signal, according to certain embodiments.

FIG. 2 illustrates a simplified representation of a system and process for generating random numbers via a quantum random number generator, according to certain embodiments.

FIG. 3 illustrates a simplified diagram of a quantum random number generator, according to certain embodiments.

FIG. 4 illustrates a simplified diagram of a quantum random number generator with multiple amplifiers, according to certain embodiments.

FIG. 5 illustrates a simplified diagram of a quantum random number generator with amplifiers, according to certain embodiments.

FIG. 6 illustrates a simplified diagram of a quantum random number generator with corrective bias feedback, according to certain embodiments.

FIG. 7 illustrates a flowchart of a method for generating a quantum-generated random number, according to certain embodiments.

### DETAILED DESCRIPTION

Generating true random numbers may have uses in cryptography, information security, and other fields. In order to generate random numbers, a random number generator must have a source of entropy, or randomness. One technique of generating random numbers may be to exploit quantum phenomena and translating the quantum phenomena into an electrical signal. Whereas other electrical signals (e.g., radio waves) may have a discernable pattern such as a sinusoidal wave, electrical signals generated via quantum phenomena may be noise, or random signals.

Various devices may be used to generate noise using the quantum phenomena. For example, a metal-oxide semiconductor field-effect transistor (MOSFET), a junction field-effect transistor (JFET), and/or a tunnel diode may all have a state in which noise is produced via quantum phenomena. For example, a tunnel diode may have an operating bias point at which electrons begin to tunnel through the diode at random. As this happens, the noise generated from the tunneling electrons may generate electrical noise. A quantum-generated random number may be then be generated by digitizing the noise and sampling a portion of an associated digital signal. Therefore, noise sources that utilize quantum phenomena may be used as a source of entropy for a random number generator.

One issue with this method may be a signal strength associated with noise from quantum phenomena. For example, a signal strength of noise generated by the tunnel diode may be on the order of 1 mV. A signal this faint may be easily overpowered by background signals such as electromagnetic interference, appliances, power sources, and other such devices. As these devices may operate cyclically, the associated background signals may superimpose a detectable pattern, such as sinusoidal waves, on the noise. The entropy, or randomness, associated with the noise may therefore be destroyed. Furthermore, because the noise may be so weak, quantum random number generators may be susceptible to attack by bad actors. For example, the unwanted signal may be intentionally broadcast by a bad actor such that the randomness of the noise is destroyed.

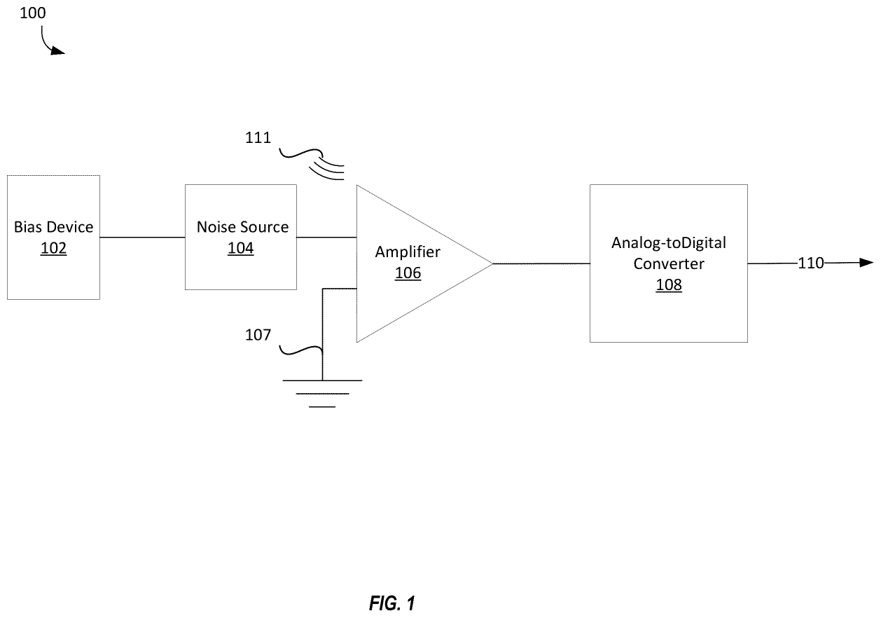

FIG. 1 illustrates a simplified diagram of a quantum random number generator (QRNG) 100 with an unwanted signal 111, according to certain embodiments. The QRNG 100 may include a bias device 102, a noise source 104, an amplifier 106, and an analog-to-digital converter (ADC) 108. The ADC 108 may output a quantum random number stream 110.

The bias device 102 may be configured to bias the noise source 104. The bias device 102 may provide a voltage or a current to the noise source 104. The bias device 102 may include a voltage-based bias device, such as a Low Drop Out regulator. In other embodiments, the bias device 102 may include a current-based bias. The bias device 102 may be tunable, such that the output of the bias device 102 matches a bias point of the noise source 104. The bias point may be associated with an operating point of a diode or some other similar point of a different device. For example, the noise source 104 may include a tunnel diode. The operating point of the tunnel diode may be a low direct current (DC) operating bias point. Thus, in some embodiments, the bias device 102 may be configured to provide a DC bias to the noise source 104.

The noise source 104 may include a semiconductor device. Examples of suitable electronic semiconductor devices may include a metal-oxide semiconductor field-effect transistor (MOSFET), a junction field-effect transistor (JFET), a tunnel diode or other diode, or any other suitable device. The noise source 104 may generate a first noise based on quantum effects such as electron tunneling. The noise source 104 may therefore be a quantum noise source. The first noise generated from the noise source 104 may be the product of non-deterministic, entropy-producing activity. Thus, the noise source 104 may be used as a source of entropy for the QRNG 100.

The noise produced by the noise source 104 may include shot noise (e.g., if the noise source 104 includes a tunnel diode). The noise from the noise source 104 may then be relatively weak as compared to the unwanted signal 111. The noise source 104 may function at a low direct current (DC) operating bias point in order to extend the noise source's lifetime and preserve its quantum characteristics.

The amplifier 106 may amplify a voltage response or output (the noise) of the noise source 104 resulting in an analog signal. In some embodiments, the amplifier may be programmable to control a dB value runtime within a range of about 10 dB to 100 dB. In some embodiments, the amplifier 106 may be configured as a differential amplifier. In this case, the noise source 104 may be connected to a first channel of the amplifier 106. A second channel of the amplifier 106 may be connected to the ground 107. The amplifier 106 may then generate an analog signal from the difference between inputs received on the first channel and the second channel (that is, the noise from the noise source 104 and the ground 107).

The analog signal may then be provided to the ADC 108. The ADC 108 may be configured to convert an analog signal to a digital signal. The ADC 108 may have an operating range (e.g., 1 V peak to peak). The ADC 108 may represent a first portion of analog signal characterized by a first signal strength above a threshold as a “1,” and a second portion of the analog signal characterized by a second signal strength below the threshold as a “0.” The ADC 108 may also include a sampling device. The sampling device may include a sampling digitizer, a vector network analyzer, an oscilloscope, a spectrum analyzer, and other suitable devices. The sampling device may be configured to extract a portion of the digital signal based at least in part on a time period. For example, the digital signal may have a signal length of 10 ns and the sampling device may extract a portion of the continuous signal over a 2 ns time period. In some embodiments, the sampling device may sample a portion of the analog signal before the analog signal is digitized. The ADC 108 may then output a digital signal. The digital signal may include the quantum random number stream 110.

The unwanted signal 111 may include electromagnetic interference (EMI), power supply noise, and other such noise. The unwanted signal 111 may be stronger than the noise generated by the noise source 104. Thus, the arrangement shown in FIG. 1 may lead to issues in the entropy or randomness generated by the QRNG 100. For example, if the noise source 104 includes a tunnel diode, the signal strength of the noise may be in the mV range. The unwanted signal 111 may have an associated signal strength higher than that of the noise, and the randomness of the noise may be destroyed.

For example, a power source near the noise source 104 may operate at the 50 Hz range. EMI of the power source may then also be in the 50 Hz range and appear as a sine wave. Because the noise source 104 may rely on non-deterministic, random phenomena to generate noise (such as electron tunneling), there may be no discernible pattern to the noise. If the EMI of the power source has a signal strength close to or stronger than the signal strength of the noise, the randomness of the noise may be destroyed, now being characterized by a 50 Hz sine wave.

Additionally, the unwanted signal 111 may add its associated signal strength to that of noise. Thus, any input received by the amplifier 106 may have a higher signal strength than that of the noise generated by the noise source 104. The analog signal provided to the ADC 108 may therefore also have a higher signal strength. The ADC 108 may therefore classify every portion of the analog signal as a “1” because the signal strength of the analog signal is higher than the threshold.

Although some sources of the unwanted signal 111 may be accidental or environmental, the unwanted signal 111 may also be generated by a bad actor. By transmitting the unwanted signal at a known frequency and/or signal strength, the bad actor may destroy the randomness of the QRNG 100 and therefore compromise the integrity of the QRNG 100. In security applications, for example, this may lead to unacceptable breaches of data etc. Therefore, there is a need for a more robust and secure system and method of generating a quantum random number. The systems and methods disclosed herein may address these issues and lead to more secure random number generation.

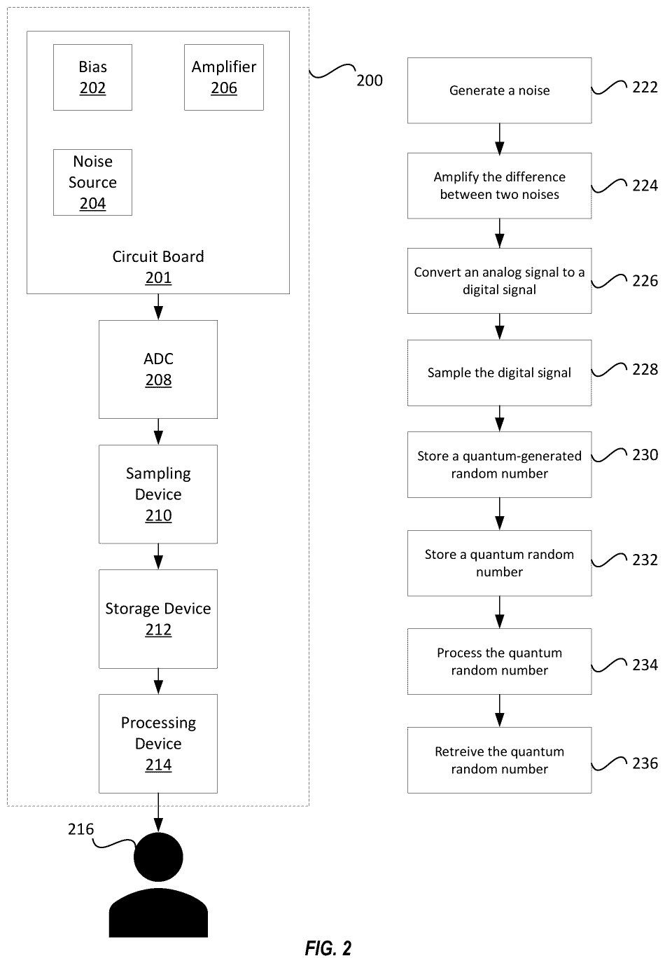

FIG. 2 illustrates a simplified representation of a system and process for generating random numbers via a quantum random number generator (QRNG) 200, according to certain embodiments. The QRNG 200 may include a circuit board 201. The circuit board 201 may include a bias device 202, a noise source 204, and an amplifier 206. Although the circuit board 201 only shows one bias device 202, noise source 204, and amplifier 206, any number of these devices may be present on the circuit board 201. The circuit board 201 may include other components (not shown) such as an I/O device, circuits and components for erasing data, and other such components. Furthermore, the QRNG 200 may also include multiple circuit boards similar to the circuit board 201. In some embodiments, the circuit board 201 may include an Application-Specific Integrated Circuit (ASIC).

The bias device 202 may be configured to bias the noise source 204. The bias device 202 may provide a voltage or a current to the noise source 204. The bias device 202 may include a voltage-based bias device, such as a Low Drop Out regulator. In other embodiments, the bias circuit may include a current-based bias. The bias device 202 may be tunable, such that the output of the bias device 202 matches a bias point of the noise source 204. The bias point may be associated with an operating point of a diode or some other similar point of a different device.

The noise source 204 may include a semiconductor device. Examples of suitable electronic semiconductor devices may include a MOSFET, a JFET, a tunnel diode or other diode, or other such device. The noise source 204 may generate a first noise based on quantum effects such as electron tunneling. The noise source 204 may therefore be a quantum noise source. The first noise generated from the noise source 204 may therefore be the product of non-deterministic, entropy-producing activity. Thus, the noise source 204 may be used as a source of entropy for the QRNG 200.

The amplifier 206 may amplify a voltage response or output (the first noise) of the first noise source 204 and a second noise generated by a second noise source, resulting in an analog signal. The amplifier 206 may include a single ended low noise amplifier, op-amp, or other suitable device. In some embodiments, the amplifier 206 may be programmable. The amplifier 206 may be programmed to control a dB value runtime within a range of about 10 dB to 100 dB. In other embodiments, the amplifier 206 may amplify a signal by a fixed value (e.g., 100 dB).

In some embodiments, the amplifier 206 may be configured as a differential amplifier. In this case, the noise source 204 may be connected to a first input channel of the amplifier 206. A second noise source may be connected to a second input channel of the amplifier 206. The amplifier 206 may then generate an analog signal from the difference between inputs received on the first input channel and the second input channel (that is, the noise from the noise source 204 and a second noise from the second noise source).

In another embodiment, the amplifier 206 may be configured as a buffer. In that case, the noise source 204 may be connected to the first channel of the amplifier 206. A corrective feedback signal may be provided to the amplifier 206 via the second channel of the amplifier 206. The corrective feedback signal may be provided, at least in part, by an analog accumulator, an analog integrator, and/or other appropriate devices. Other configurations would be obvious to one of ordinary skill in the art based on the embodiments described herein.

The QRNG 200 may also include an analog-to-digital converter (ADC) 208. The ADC 208 may be configured to convert an analog signal to a digital signal. The ADC 208 may have an operating range (e.g., 1 V peak to peak). The ADC 208 may represent a first portion of analog signal characterized by a first signal strength (e.g., above a certain threshold such as 1 V) as a “1,” and a second portion of the analog signal characterized by a second threshold (e.g., below the certain threshold) as a “0.”

The QRNG 200 may also include a sampling device 120. The sampling device may include a sampling digitizer, a vector network analyzer, an oscilloscope, a spectrum analyzer, and other suitable devices. The sampling device 210 may be configured to extract a portion of the digital signal based at least in part on a time period. For example, the digital signal may have a signal length of 10 ns and the sampling device 210 may extract a portion of the continuous signal over a given time period (e.g., 2 ns). The portion of the digital signal may represent one or more quantum-generated random numbers.

The QRNG 200 may also include a storage device 212. The storage device 212 may include a random access memory (RAM), a hard disk drive (HDD), a solid state drive (SDD), a vendor neutral archive (VNA) storage device, or other suitable devices. The ADC 208, the sampling device 210, and the storage device 212 may be included in a single device, may be combined in any possible combination, or may all be separate.

The ADC 208, the sampling device 210, and the storage device 212 may also be in a different order than is shown in FIG. 1. For example, the sampling device 210 may extract a portion of the analog signal, then the ADC 208 may convert the portion of the analog signal into a digital signal. The digital signal may represent one or more quantum-generated random numbers. Other configurations would be obvious to a person of ordinary skill in the art based on the embodiments described herein.

The QRNG 200 may also include a processing device 214. The processing device 214 may include a Field Programmable Gate Array (FPGA). The FPGA may access the portion of the digital signal and perform functions to modify the portion of the digital signal through semi-pseudorandom techniques. The techniques may include applying a hash function or folding. Other techniques may be applied, such as those techniques specified by the National Institute of Technology in SP-800-90A.

At step 222, the process may include generating a noise (sometimes “first noise”). The noise may be generated by the noise source 204 in response to a bias provided by the bias device 202. The noise may be generated through quantum effects and therefore be non-deterministic. The noise source 204 may therefore be a quantum noise source. Because the noise may be non-deterministic, the noise source 204 may act as a source of entropy for the QRNG 200. The noise may be provided to the amplifier 206 via a first input channel.

The QRNG 200 may include a second noise source and associated bias device either included on the circuit board 201 or on a second circuit board. The second noise source may generate a second noise in response to a bias provided by the associated biasing device. Like the noise from the noise source 204, the second noise may be generated through quantum effects and therefore be non-deterministic. The second noise may be provided to the amplifier 206 on a second input channel.

The amplifier 206 may be configured as a differential amplifier. In this configuration, signals (here, the noise from the noise source 204) received on the first input channel of the amplifier 206 may be positive. Signals (here, the second noise) received on the second input channel may be negative, or inverted. Thus, when the first noise and the second noise are combined by the amplifier 206, a difference between the first noise and the second noise may be generated. Because the first noise and the second noise may be non-deterministic (or random), the difference between the first noise and the second noise may also be random. Thus, the difference between the first noise and the second noise may be used a source of entropy for the QRNG 200.

At step 224, the process may include amplifying, by the amplifier 206, the difference between the first noise and the second noise. The amplified difference between the first noise and the second noise may be used to generate a first amplified analog signal. The amplifier 206 may then output the first amplified analog signal.

In some embodiments, there may be multiple circuit boards similar to the circuit board 201. The analog signals from each of the multiple circuit boards may then be provided to one or more amplifiers. The final amplifier of the one or more amplifiers may be configured as a differential amplifier. The final amplifier may output a final analog signal.

At step 226, the ADC 208 may convert the analog signal to a digital signal that is equivalent to and corresponds to the analog signal. Because the analog signal may represent the difference between two non-deterministic noises and thus be random, the digital signal may also be random. The digital signal may correspond to the analog signal by representing the analog signal as a series of random, discreet numbers such as a 1 or a 0. The digital signal may be a quantum random number stream.

Alternating current (AC) coupling may be performed by the ADC 208 prior to converting the analog signal to the digital signal. A differential process may provide an additional AC coupling function, removing any (large) common mode direct current (DC) value present in each individual channel. If the first channel and the second channel were not AC coupled, their mean values may be a positive non-zero value, having a much larger order than the first noise and the second noise. For example, if the first noise and/or the second noise is a shot noise (having a strength approximately within the mV range) and assuming ˜3.3V of both the first channel and the second channel with a 5V rail, the amplifier 106 may amplify the common mode DC and the first and second noises. Thus, without AC coupling, the DC component of the input may dominate the input range of the analog-to-digital converter stage (ADC). In some embodiments, there may not be a need for a separate AC coupling stage. For example, if the amplifier 206 is configured as a differential amplifier, the amplifier 206 may effectively remove any DC components of the first noise received on the first input channel and the second noise received on the second input channel.

At step 228, the digital signal may be sampled by the sampling device 210. The sampling device 210 may be included in the ADC 208 or may be a separate device. The sampling device 210 may sample only a portion of the quantum random number stream. For example, the quantum random number stream may have a period of 10 ns and the sampling device 210 may extract a portion of the quantum random number stream over a given time period (e.g., 2 ns).

In some embodiments, the sampling device 210 may receive the analog signal before it is converted to the digital signal by the ADC 208. Because the analog signal may be generated based on non-deterministic noise emitted by the first noise source 204 and the second noise source, the portion of the analog signal may be random. The portion of the analog signal may then be digitized by the ADC 208, creating a digital signal. The digital signal may correspond to the analog signal, and therefore represent the randomness of the analog signal as a quantum random number stream including one or more quantum-generated random numbers.

At step 230, the quantum-generated random number(s) may be stored at the storage device 212. The storage device 212 may be a part of the unitary device including the ADC 208, the sampling device 210, and the storage device 212, or the storage device may be a separate device. The storage device 212 may be volatile memory such as RAM, SDRAM, or other suitable formats. The storage device 212 may additionally or alternatively include non-volatile memory such as an HDD or SSD.

At step 234, the quantum-generated random number may be processed by the processing device 214. The processing device 214 may apply one or more semi-pseudorandom techniques to the quantum-generated random number. For example, the techniques may include applying a hash function or folding. Other techniques may be applied, such as those techniques specified by the National Institute of Technology in SP-800-90A.

In some embodiments, the processing device 214 may be included in a unitary device including the ADC 208, the sampling device 210, the storage device 212, and the processing device 214. In other embodiments, the processing device 214 and the storage device 212 be included in a single device. In yet another embodiment, the processing device 214 may be a separate device. Furthermore, the processing device 214 may process the quantum-generated random number before being stored by the storage device 212.

At step 236, the quantum-generated random number may be retrieved by a user 216. The user 216 may retrieve the quantum-generated random number directly from the QRNG 200, or via an intermediary device such as a personal computer, tablet, mobile phone, or other suitable device. In some embodiments, the user 216 may retrieve the quantum-generated random number from the storage device 212 and/or the processing device 214. Retrieving the quantum-generated random number may cause the quantum-generated random number to be deleted, erased, or overwritten from one or more components of the QRNG 200.

The arrangements and process described in relation to FIG. 2 are merely example embodiments. The QRNG 200 may include more or less components than are shown in varying configurations, some of which are described herein. Furthermore, the process described in FIG. 2 may exclude certain steps or be performed in a different order. For example, in an embodiment, the QRNG 200 may not include a storage device 212 and/or a processing device 214. The process may therefore not include storing the quantum-generated random number, nor processing the quantum-generated random number. In that case, the quantum-generated random number may be retrieved by the user 216 directly from the ADC 208 and/or the sampling device 210.

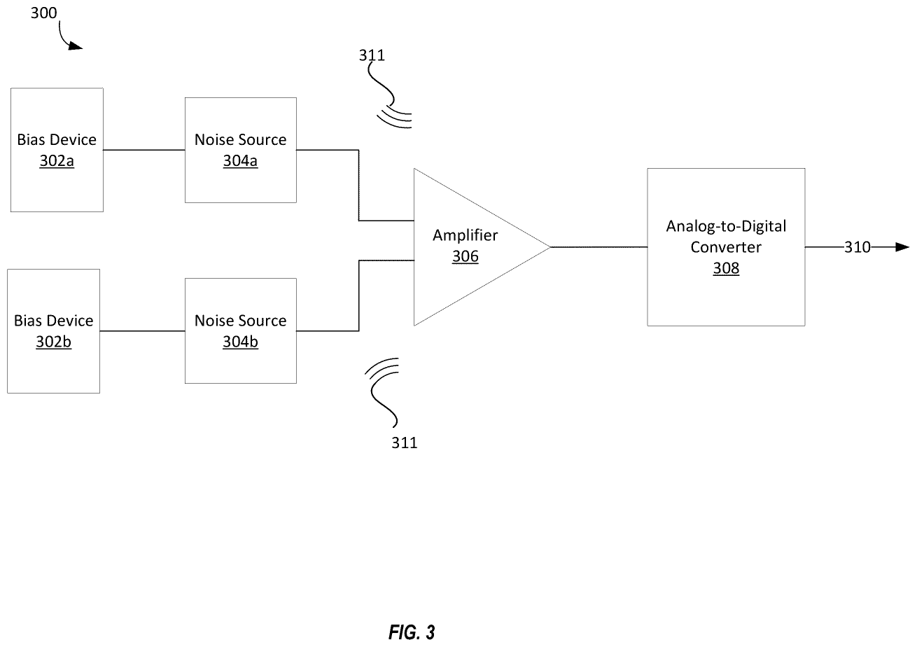

FIG. 3 illustrates a simplified diagram of a quantum random number generator (QRNG) 300, according to certain embodiments. The QRNG 300 may be similar to some or all of the QRNG 200 in FIG. 2. Thus, the QRNG 300 may be able to perform some or all of the processes described in relation to FIG. 2. The QRNG 300 may include bias devices 302a-b, noise sources 304a-b, an amplifier 306, and an analog-to-digital converter (ADC) 308. The ADC 308 may output a digital signal as a quantum random number stream 310. An unwanted signal 322 may be incident on some or all of the QRNG 300.

Some or all of the components shown in the QRNG 300 may be included on a circuit board similar to the circuit board 201 in FIG. 2. In some embodiments, QRNG 300 may include multiple circuit boards. For example, the bias device 302a and first noise source 304a may be included on a first circuit board. The bias device 302b and the second noise source 304b may be included on a second circuit board. The amplifier 306 and the ADC 308 may be on a third circuit board. The specific arrangement is not intended to be limited by the exemplary embodiment shown in this figure.

The bias devices 302a-b may provide a voltage or a current to each corresponding noise source 304a-b. The bias devices 302a-b may include a voltage-based bias device, such as a Low Drop Out regulator. In other embodiments, at least one of the bias devices may include a current-based bias to provide a DC bias. The bias devices 302a-b may be tunable, such that the output of the bias devices 302a-b matches a bias point associated with each corresponding noise source 304a-b. The bias point may be associated with an operating point of a diode or some other similar point of a different device. In other words, each of the bias devices 302a-b may be specifically tuned to the corresponding noise source 304a-b. Thus, the bias devices 302a-b may provide the same bias (e.g., 1 V) or different biases, depending on the corresponding noise source 304a-b.

The noise sources 304a-b may include one or more semiconductor devices. Examples of semiconductor devices may include a MOSFET, JFET, a tunnel diode or other diode, or any other suitable device. The noise sources 304a-b (sometimes the first noise source 304a and second noise source 304b) may generate a first and second noise, respectively, based on quantum effects such as electron tunneling. The noise sources 304a-b may therefore be quantum noise sources. The first noise generated from the first noise source 304a may be the product of non-deterministic, entropy-producing activity. Similarly, the second noise source 304b may generate a second noise, also based on quantum effects. Thus, the first noise source 304a and the second noise source 304b may be both used as a source of entropy for the QRNG 300.

The amplifier 306 may be an op-amp configured as a differential amplifier. The amplifier 306 may be configured to receive the first noise on a first input channel and to receive the second noise on a second input channel. In this configuration, signals the first noise source 304a received on the first input channel of the amplifier 306 may be positive. The second noise received on the second input channel may be negative, or inverted. Thus, when the first noise and the second noise are combined by the amplifier 306, a difference between the first noise and the second noise may be generated. Because the first noise and the second noise may be non-deterministic (or random), the difference between the first noise and the second noise may also be random. The amplifier 306 may then amplify a difference between the first noise and the second noise to generate a first amplified analog signal.

The first amplified analog signal may then be provided to the ADC 308. The ADC 308 may be configured to convert an analog signal to a digital signal. The ADC 308 may also include a sampling device. The sampling device may include a sampling digitizer, a vector network analyzer, an oscilloscope, a spectrum analyzer, and/or other suitable devices. The sampling device may be configured to extract a portion of the digital signal based at least in part on a time period. For example, the digital signal may have a signal length of 10 ns and the sampling device may extract a portion of the continuous signal over a given time period (e.g., 2 ns). In some embodiments, the sampling device may sample a portion of the first amplified analog signal before the first amplified analog signal is digitized. The ADC 308 may then output the quantum random number stream 310.

The unwanted signal 311 may be similar to the unwanted signal 111 in FIG. 1. The unwanted signal 311 may therefore include electromagnetic interference (EMI), power supply noise, and other such noise. Also similar to the unwanted signal 111, a signal strength of the unwanted signal 311 may be stronger than signal strengths associated with the first noise sand the second noise. However, the first noise and the second noise may both be subject to the unwanted signal 311. Thus, as in FIG. 1, the randomness of the first noise and the second noise may be compromised. In the example of the power source described in relation to FIG. 1, both the first noise and the second noise may be characterized by a 50 Hz sine wave. Furthermore, as the first noise and the second noise may be exposed to the unwanted signal 311 at substantially the same time, both the first noise and the second noise may be in phase with each other as they are provided to the amplifier 306.

As discussed above, the first noise received on the first input channel is positive, and the second noise received on the second input channel is negative. As both the first noise and the second noise are in phase upon being provided to the amplifier 306, the unwanted signal 311 may be cancelled out. In other words, because the second input channel may take the negative of the second noise (and therefore negative of the unwanted signal 311), any influence from the unwanted signal 311 may be nullified. When the first noise and the second noise are combined by the amplifier 306, the entropy associated with both the first noise and the second noise may be restored and/or increased.

To understand how a differential noise source architecture combines the first and second noises (sometimes referred to as X and Y) and contributes to a final entropy content, statistical representation and analysis techniques may be used. Each source may contribute a characteristic noise profile represented by a Poisson distribution with individual means μX, μY and individual standard deviations: σX, σY. The result of combining the two independent noise sources is simply the statistical difference of each noise source. The mean and standard deviation of the combination of the two sources is the differential output signal noted as μ(X−Y) and σ(X−Y) respectively.

The mean of the difference between X and Y is the difference of the mean of X and the mean of Y (μ(X−Y)=μX−μY). If μX is equal to μY then the mean of the resulting signal may be approximately zero (0). This represents an amplified signal with a probability distribution maximized at the 0 (voltage) point.

Within the differential noise source setup, the standard deviation (SD) of combined X and Y may be greater than the individual standard deviations of X and Y (σ²(X−Y)=σ²X−σ²Y). X and Y may be from the same device family, therefore σX=σY (approximately). Thus, σ² (X−Y)=2σ²X, σ(X−Y)=√2 σX, so σ(X−Y)=1.41 σX. Therefore, the resulting amplified signal may include a SD greater than the SD of each individual noise source, by a factor of square root of 2 or 1.41. Because entropy is proportional to SD, the differential noise source setup may improve available entropy when compared to just using a single noise source. Thus, the QRNG 300 may not only nullify interference, accidental or intentional, but may increase an effectiveness of with the QRNG 300 in generating truly random numbers.

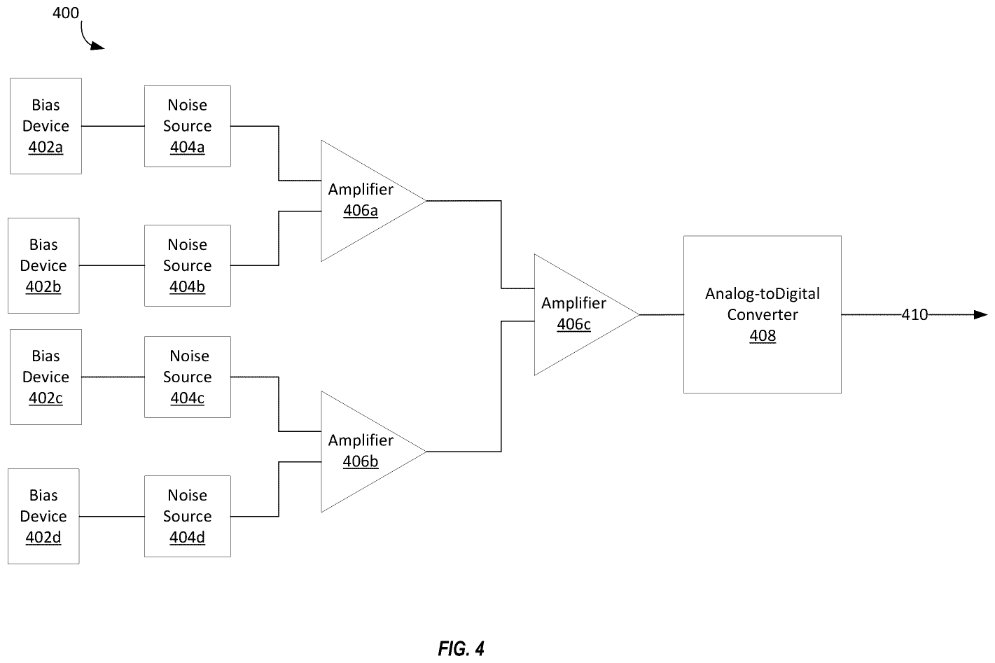

FIG. 4 illustrates a simplified diagram of a quantum random number generator (QRNG) 400 with multiple amplifiers 406a-c, according to certain embodiments. The QRNG 400 may be similar to some or all of the QRNG 200 in FIG. 2. Thus, the QRNG 400 may be able to perform some or all of the process described in relation to FIG. 2. The QRNG 400 may include bias devices 402a-d, noise sources 404a-d, amplifiers 406a-c, and an analog-to-digital converter (ADC) 408. The ADC 408 may output a digital signal as a quantum random number stream 410. Although no unwanted signal is shown in FIG. 4, it should be understood that the relevant description of the unwanted signal 311 and QRNG 300 in FIG. 3 may apply to some or all of QRNG 400.

Some or all of the components shown in the QRNG 400 may be included on a circuit board similar to the circuit board 201 in FIG. 2. In some embodiments, QRNG 400 may include multiple circuit boards. For example, each of the bias devices 402a-d and the noise sources 404a-d may be included on associated circuit boards (e.g., the bias device 402a and the first noise source 404a on a first circuit board, the bias device 402b and the second noise source 404b on a second circuit board, and so on). The multiple amplifiers 406a-c and the ADC 408 may be on a different circuit board. Many other configurations may be possible. Each of the multiple amplifiers 406a-c may be configured as a differential amplifier. The specific arrangement is not intended to be limited by the exemplary embodiment shown in this figure.

The bias devices 402a-d may be similar to the bias devices 302a-b in FIG. 3. Thus, one or more of the bias devices 402a-d may include a voltage-based bias device, such as a Low Drop Out regulator. In other embodiments, the bias devices 402a-d may include a current-based bias to provide a DC bias. The bias devices 402a-d may be tunable, such that the output of the bias devices 402a-d matches a bias point associated with each corresponding noise source 404a-d, and each of the bias devices 402a-d may be specifically tuned to the corresponding noise source 404a-d.

Also similar to FIG. 3, the noise sources 404a-d may be similar to the noise sources 304a-b and include one or more semiconductor devices. Examples of semiconductor devices may include a MOSFET, a JFET, a tunnel diode or other diode, or any other suitable device. The noise sources 404a-d (sometimes the first noise source 404a through fourth noise source 404d, respectively) may each generate noise, respectively, based on quantum effects such as electron tunneling and therefore be quantum noise sources.

The first noise source 404a may generate a first noise in response to a bias provided by the bias device 402a. Similarly, the second noise source 404b may generate a second noise in response to a bias provided by the bias device 402b. The first amplifier 406a may receive the first noise from the first noise source 404a on a first input channel and the second noise from the second noise source 404b on a second input channel. The first noise received on the first channel may be positive, and the second noise received on the second channel may be negative. The first amplifier 406a may then combine the first noise and the second noise to create a difference between the first noise and the second noise. The first amplifier 406a may then use the difference to generate a first amplified analog signal. Similar to FIG. 3, any interference from an unwanted signal may therefore be nullified as the first noise and second noise are combined.

The third noise source 404c may generate a third noise in response to a bias provided by the bias device 402c. Similarly, the fourth noise source 404d may generate a fourth noise in response to a bias provided by the bias device 402d. The second amplifier 406b may receive the third noise from the third noise source 404c on a third input channel and the fourth noise from the fourth noise source 404d on a fourth input channel. The third noise received on the third channel may be positive, and the fourth noise received on the fourth channel may be negative. The second amplifier 406b may then combine the third noise and the fourth noise to create a difference between the third noise and the fourth noise. The second amplifier 406b may then use the difference to generate a second amplified analog signal. Similar to FIG. 3, any interference from an unwanted signal may therefore be nullified as the third noise and fourth noise are combined.

The first amplifier 406a may then provide the first amplified analog signal to the third amplifier 406c. The third amplifier 406c may receive the first amplified signal on a fifth input channel. The second amplifier 406b may provide the second amplified analog signal to the third amplifier 406c on a sixth input channel. The third amplifier 406c may then combine the first amplified analog signal and second amplified analog signal to create a difference between the first amplified analog signal and second amplified analog signal. The difference may be used to generate a combined analog signal. An unwanted signal may be incident on the first amplified signal and the second amplified analog signal. Because the third amplifier 406c may be configured as a differential amplifier, any interference from the unwanted signal may be nullified. Thus, in some embodiments, the configuration described in FIG. 4 may include a redundant process of nullifying interference from unwanted signals.

The combined analog signal may then be provided to the ADC 408. The ADC 408 may be configured to convert an analog signal to a digital signal. The ADC 408 may also include a sampling device. The sampling device may include a sampling digitizer, a vector network analyzer, an oscilloscope, a spectrum analyzer, and other suitable devices. The sampling device may be configured to extract a portion of the digital signal based at least in part on a time period. For example, the digital signal may have a signal length of 10 ns and the sampling device may extract a portion of the continuous signal over a given time period (e.g., 2 ns). In some embodiments, the sampling device may sample a portion of the first amplified analog signal before the first amplified analog signal is digitized. In either case, the ADC 408 may then output the quantum random number stream 410.

Besides redundancy in nullifying any interference from an unwanted signal, the configuration illustrated in FIG. 4 may also increase the effectiveness of the QRNG 400 as compared to other configurations. As the entropy associated with the first and second amplified analog signals may each be 1.41 σX, or the square root of two times the standard deviation of a single noise source, the entropy associated with the combined analog signal may be 2 σX. Thus, the configuration illustrated in FIG. 4 may be characterized by higher entropy than other configurations. Although FIG. 4 only shows four noise sources 404a-d and three amplifiers 406a-c, any number of noise sources and amplifiers may be combined using the techniques and architecture described herein.

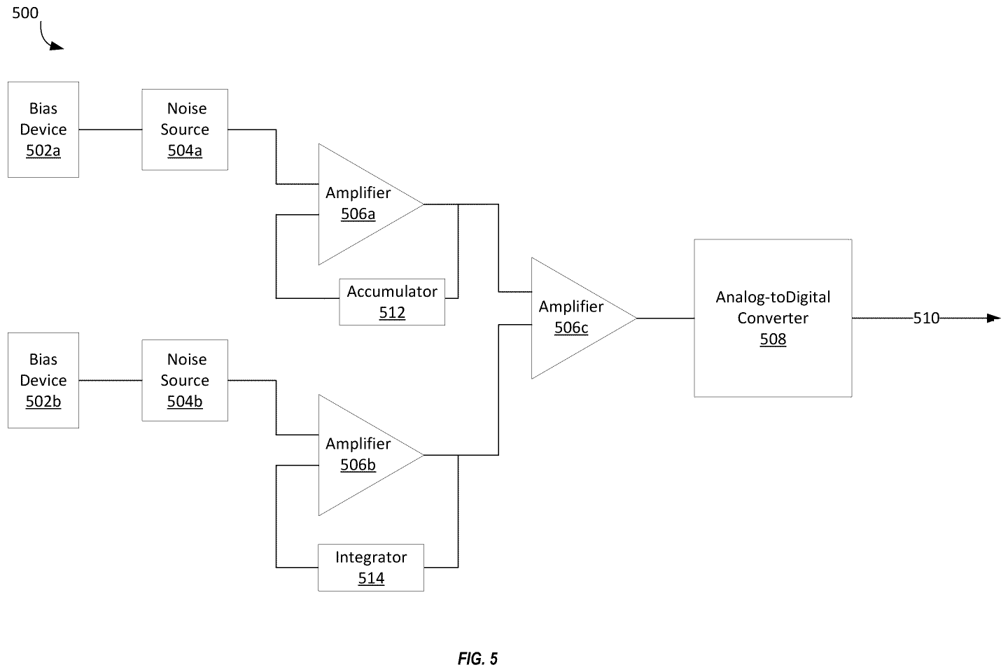

FIG. 5 illustrates a simplified diagram of a quantum random number generator (QRNG) 500 with amplifiers 506a-c, according to certain embodiments. The QRNG 500 may be similar to some or all of the QRNG 200 in FIG. 2. Thus, the QRNG 500 may be able to perform some or all of the process described in relation to FIG. 2. The QRNG 500 may include bias devices 502a-b, noise sources 504a-b, amplifiers 506a-c, and an analog-to-digital converter (ADC) 508. The ADC 508 may output a digital signal as a quantum random number stream 510. The QRNG 500 may also include an analog accumulator 512 and an analog integrator 514. Although no unwanted signal is shown in FIG. 5, it should be understood that the description of the unwanted signal 311 and the QRNG 300 in FIG. 3 may apply to some or all of QRNG 500.

The bias devices 502a-b may be similar to the bias devices 302a-b in FIG. 3 and provide a voltage or a current to each corresponding noise source 504a-b. Each of the bias devices 502a-b may be specifically tuned to the corresponding noise source 504a-b. Similarly, the noise sources 504a-b may be similar to the noise sources 304a-b in FIG. 3, and include semiconductor devices such as a MOSFET, a JFET, a tunnel diode, other diodes, and other suitable devices.

In response to a bias provided by an associated bias device of the bias devices 502a-b, the first noise source 504a and the second noise source 504b may generate a first noise and a second noise, respectively. The first and second noise may be generated through non-determinate quantum phenomena such as electron tunneling. Because the first and second noises may be generated by non-determinate quantum phenomena, the first and second noises may be random and be used as a source of entropy for the QRNG 500.

The bias device 502a, the first noise source 504a may also be configured such that the first noise source 504a generates a first noise in response to a bias provided by the bias device 502a. The first noise may be provided to the first amplifier 506a on a first input channel. The first amplifier 506a may be configured as a buffer. The first noise may then be amplified and output as an analog signal. The analog signal may be used at least in part to generate a first corrective feedback signal. The first corrective feedback signal may be provided to the analog accumulator 512 or other such register. The first corrective feedback signal may then be provided to a second input channel of the first amplifier 506a. Because the first amplifier 506a may be configured as a buffer, it may preserve a signal quality of the first noise. The first amplifier 506a may then output a first corrected noise.

The bias device 502b, the second noise source 504b may also be configured such that the second noise source 504b generates a second noise in response to a bias provided by the bias device 502b. The second noise may be provided to the second amplifier 506b via a third input channel. The second amplifier 506b may also be configured as a buffer, similar to the first amplifier 506a. However, a second corrective signal may be provided to the analog integrator 514. The analog integrator may utilize the output of the second amplifier 506b to determine a rate of change associated with the second noise. The analog integrator 514 may then provide the second corrective signal to the second amplifier 506b via a fourth input channel. The second amplifier 506b may then output a second corrected noise.

The first corrected noise may then be provided to the third amplifier 506c via a fifth input channel. The second corrected noise may be provided to the third amplifier 506c via a sixth input channel. The third amplifier 506c may be configured as a differential amplifier. Therefore, the first corrected noise received on the fifth input channel may be positive, and the second corrected noise received on the sixth input channel may be negative. When the first corrected noise and the second corrected noise are combined, a difference between the first corrected noise and the second corrected noise may be generated. As is described in FIG. 3, any interference from an unwanted signal such as the unwanted signal 311 may be nullified.

In some embodiments, the first corrective signal and the second corrective signal may be the same. In some embodiments, only one corrective signal may be provided to one noise source 504a-b. In some embodiments, the first corrective signal and second corrective signal may be provided to a corresponding bias device 502a-b.

The third amplifier 506c may then output an amplified analog signal based on the difference between the first corrected noise and the second corrected noise. The amplified analog signal may be received by the ADC 508. The ADC 508 may be configured to convert an analog signal to a digital signal. The ADC 508 may also include a sampling device. The sampling device may include a sampling digitizer, a vector network analyzer, an oscilloscope, a spectrum analyzer, and/or other suitable devices. The sampling device may be configured to extract a portion of the digital signal based at least in part on a time period. For example, the digital signal may have a signal length of 10 ns and the sampling device may extract a portion of the continuous signal over a given time period (e.g., 2 ns). The portion of the digital signal may be one or more quantum-generated random numbers (or, the quantum random number stream 510). In some embodiments, the sampling device may sample a portion of the first amplified analog signal before the first amplified analog signal is digitized. In either case, the ADC 508 may then output the quantum random number stream 510.

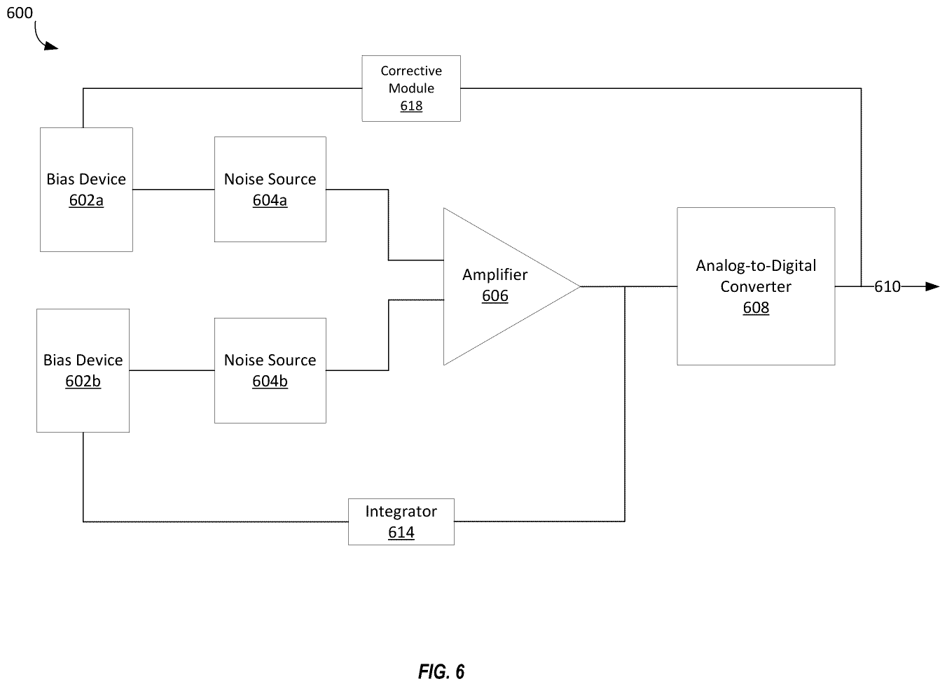

FIG. 6 illustrates a simplified diagram of a quantum random number generator (QRNG) 600 with corrective bias feedback, according to certain embodiments. The QRNG 600 may be similar to some or all of the QRNG 200 in FIG. 2. Thus, the QRNG 600 may be able to perform some or all of the process described in relation to FIG. 2. The QRNG 600 may include bias devices 602a-b, noise sources 604a-b, an amplifier 606, and an analog-to-digital converter (ADC) 608. The ADC 608 may output a digital signal as a quantum random number stream 610. The QRNG 600 may also include an integrator 614 and a corrective module 618. Although no unwanted signal is shown in FIG. 6, it should be understood that the description of the QRNG 300 in FIG. 3 may apply to some or all of QRNG 600.

The bias devices 602a-b may be similar to the bias devices 302a-b in FIG. 3 and provide a voltage or a current to each corresponding noise source 604a-b. Each of the bias devices 602a-b may be specifically tuned to the corresponding noise source 604a-b. Similarly, the noise sources 604a-b may be similar to the noise sources 304a-b in FIG. 3, and include semiconductor devices such as a MOSFET, a JFET, a tunnel diode, other diodes, and other suitable devices.

In response to a bias provided by an associated bias device of the bias devices 602a-b, the first noise source 604a and the second noise source 604b may generate a first noise and a second noise, respectively. The first and second noise may be generated through non-determinate quantum phenomena such as electron tunneling. Because the first and second noises may be generated by non-determinate quantum phenomena, the first and second noises may be random.

The amplifier 606 may be an op-amp configured as a differential amplifier. The amplifier 606 may be configured to receive the first noise on a first input channel and to receive the second noise on a second input channel. In this configuration, signals the first noise source 604a received on the first input channel of the amplifier 606 may be positive. The second noise received on the second input channel may be negative, or inverted. Thus, when the first noise and the second noise are combined by the amplifier 606, a difference between the first noise and the second noise may be generated. Because the first noise and the second noise may be non-deterministic (or random), the difference between the first noise and the second noise may also be random. The amplifier 606 may then amplify a difference between the first noise and the second noise to generate a first amplified analog signal.

The first amplified analog signal may then be provided to the ADC 608. The ADC 608 may be configured to convert an analog signal to a digital signal. The ADC 608 may also include a sampling device. In some embodiments, the sampling device may sample a portion of the first amplified analog signal before the first amplified analog signal is digitized. The ADC 608 may then output the quantum random number stream 610.

The first noise source 604a and the second noise source 604b may have a bias window. The first and second noise generated by the respective noise sources 604a-b may be optimized when the respective bias device 602a-b provides a bias within the bias window. For example, if the one or more of the noise sources 604a-b includes a tunnel diode, the bias window may be between 1.2 V-1.21 V. If the one or more of the noise sources 604a-b includes a MOSFET, the bias window may be between 0.2 V and 0.5 V. Other devices may have other bias windows. No matter the device(s) included in the noise sources 604a-b, the bias window may change according to temperature. Thus, as the QRNG 600 operates, the bias windows associated with each of the noise sources 604a-b may change. This means that to continue optimally operating the noise sources 604a-b, the bias devices 602a-b may need to be adjusted.

For example, in order to adjust the bias device 602b, the integrator 614 may be used to provide a first corrective feedback signal to the bias device 602b. The first analog signal may be provided to the integrator 614. The integrator 614 may sample the first analog signal for a time period. The time period may be longer than the signal length of the first analog signal (e.g., the first analog signal is 10 s long and the time period is 1 min). The integrator 614 may then accumulate sums of power output (signal strength) associated with the second noise generated by the second noise source 604b. The integrator 614 may use the accumulated sums to provide a first corrective feedback signal to the bias device 602b. The first corrective feedback signal may cause the bias device 602b to adjust the bias provided to the second noise source 604b such that the second noise source 604b is optimized.

In another example, the bias device 602a may be provided a second corrective feedback signal in order to provide a bias such that the first noise source 604a is optimized. The digital signal may be provided to the corrective module 618. The corrective module 618 may include an FPGA, configured to determine a power level associated with the first noise generated from the first noise source 604a over a period of time. The period of time may (e.g., the digital is 10 s long and the time period is 1 m). The corrective module 618 may use the power level to generate a second corrective signal. The second corrective signal may then be provided to the bias device 602a. In response to the second corrective signal, the bias device 602a may adjust the bias provided to the first noise source 604a such that the first noise source 604a is optimized.

Although the configurations described in FIGS. 3-6 are shown independently, one or more of the configurations may be included in a single QRNG. For example, the QRNG 200 may include a plurality of circuit boards with configurations such as the QRNG 400 in FIG. 4, combined with a plurality of circuit boards with configurations such as the QRNG 500 in FIG. 5, with corrective bias feedback shown in FIG. 6. Furthermore, although not all components in FIG. 2 are shown in FIGS. 3-6, it should be understood that any of the components shown in FIG. 2 may be present in any of the configurations shown in FIGS. 3-6.

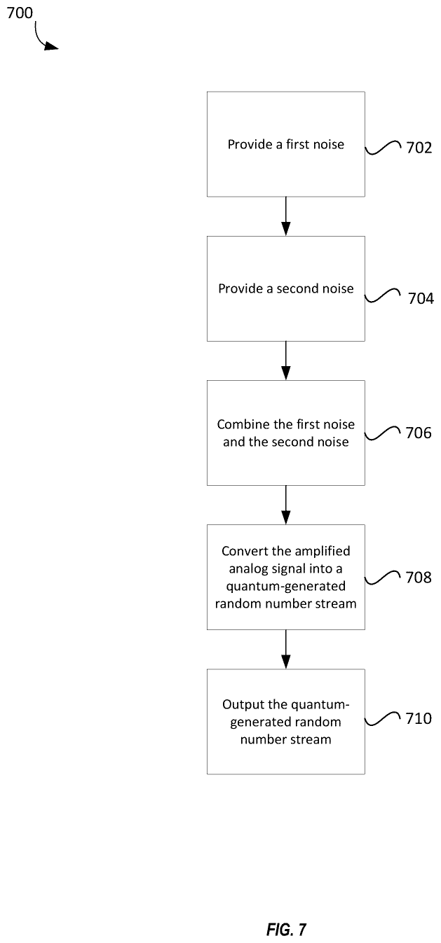

FIG. 7 illustrates a flowchart of a method 700 for generating a quantum-generated random number, according to certain embodiments. The method 700 may be performed by any of the devices and/or configurations thereof described herein. At step 702, the method 700 may include providing, by a first noise source, a first noise to an amplifier. At step 704, the method 700 may include providing, by a second noise source, a second noise to the amplifier. The first and second noise sources may be similar, for example, to the noise sources 304a-b in FIG. 3 and include one or more semiconductor devices. Examples of semiconductor devices may include a MOSFET, a JFET, a tunnel diode or other diode, or any other such device. The first noise source and the second noise source may generate a first and second noise, respectively, based on quantum effects such as electron tunneling. The noise sources may therefore be quantum noise sources. The first and second noises generated from the first and second noise sources may be the product of non-deterministic, entropy-producing activity. Accordingly, the first noise source and the second noise source may be both used as a source of entropy for a QRNG such as the QRNG 300.

At step 706, the method 700 may include combining, by the amplifier, the first noise and the second noise to generate an amplified analog signal for output. In some embodiments, the amplifier may be configured as a differential amplifier. Combining the first noise and the second noise may then include finding a difference between the first noise and the second noise. The first noise may be received by the amplifier on a first input channel and be positive. The second noise may be received on a second input channel and may be negative, or inverted. Thus, when the first noise and the second noise are combined by the amplifier a difference between the first noise and the second noise may be generated. Because the first noise and the second noise may be non-deterministic (or random), the difference between the first noise and the second noise may also be random. Furthermore, because the first noise and second noise may be combined to generate a difference, any interference from an unwanted signal may be nullified, as is described in FIG. 3. Additionally, the entropy provided through the use of a differential amplifier may be greater than the entropy provides using a single noise source.

At step 708, the method 700 may include converting, by an analog-to-digital converter device (ADC), the amplified analog signal into a quantum random number stream. The ADC may be configured to convert an analog signal to a digital signal. In some embodiments, the method 700 may also include sampling a portion of the quantum random number stream to generate a quantum random number. The sampling may be performed by a sampling device included in the ADC or by a separate device. The ADC may also include a sampling device. The sampling device may include a sampling digitizer, a vector network analyzer, an oscilloscope, a spectrum analyzer, and other suitable devices. The sampling device may be configured to extract a portion of the digital signal based at least in part on a time period. For example, the digital signal may have a signal length of 10 ns and the sampling device may extract a portion of the continuous signal over a given time period (e.g., 2 ns). In some embodiments, the sampling device may sample a portion of the amplified analog signal before the first amplified analog signal is digitized.

At step 710, the method 700 may include outputting, by the ADC device, the quantum random number stream. Outputting the quantum random number stream may include storing the quantum random number stream at a storage device such as the storage device 212 in FIG. 2. The storage device may be a part of a unitary device including the ADC, the sampling device, and/or the storage device, or the storage device may be a separate device. The storage device may include volatile memory such as RAM, SDRAM, or other suitable formats. The storage device may additionally or alternatively include non-volatile memory such as an HDD or SSD.

In some embodiments, outputting the quantum random number stream to a processing device such as the processing device 214 in FIG. 2 The processing device may include a Field Programmable Gate Array (FPGA). The FPGA may access the portion of the digital signal and perform functions modifying the portion of the digital signal through semi-pseudorandom techniques. The techniques may include applying a hash function or folding. Other techniques may be applied, such as those techniques specified by the National Institute of Technology in SP-800-90A.

In some embodiments, the method 700 may also include providing, by a first bias device, a first bias to the first noise source such that the first noise source generates the first noise. The method 700 may also include providing a second bias to the second bias source by a second bias device, such that the second noise source generates the second noise. In some embodiments, the first and second bias may provide a voltage bias, and/or a current bias, to the first noise source and the second noise source, respectively. The first bias may provide a current bias and the second bias may provide a voltage bias. In some embodiments, the first and second bias may provide the same type of bias (e.g., both current biases or both voltage biases).

In some embodiments, the method 700 may further include providing the first noise to an amplifier configured as a buffer. The amplifier may output a first corrected noise to a second amplifier via a first input channel. A second noise may be provided to the second amplifier. The second amplifier may be configured as a differential amplifier and output an amplified analog signal.

In the foregoing specification, embodiments of this disclosure are described with reference to specific embodiments thereof, but those skilled in the art will recognize that this disclosure is not limited thereto. Various features and embodiments of the above-described disclosure may be combined or may be used individually or jointly. Further, embodiments can be utilized in any number of environments and applications beyond those described herein without departing from the broader spirit and scope of the specification. The specification and drawings are, accordingly, to be regarded as illustrative rather than restrictive.

In the foregoing description, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions, to perform the methods. These machine-executable instructions may be stored on one or more machine readable mediums, such as CD-ROMs or other type of optical disks, floppy diskettes, ROMs, RAMS, EPROMs, EEPROMs, magnetic or optical cards, flash memory, or other types of machine-readable mediums suitable for storing electronic instructions. Alternatively, the methods may be performed by a combination of hardware and software.

Where components are described as being configured to perform certain operations, such configuration can be accomplished, for example, by designing electronic circuits or other hardware to perform the operation, by programming programmable electronic circuits (e.g., microprocessors, or other suitable electronic circuits) to perform the operation, or any combination thereof.

While illustrative embodiments of the application have been described in detail herein, it is to be understood that the inventive concepts may be otherwise variously embodied and employed, and that the appended claims are intended to be construed to include such variations, except as limited by the prior art.

What is claimed is:

1. A system for generating a quantum random number stream, the system comprising:
a first quantum noise source;
a first bias device, configured to bias the first quantum noise source such that the first quantum noise source generates a first noise;
a second quantum noise source;
a second bias device, configured to bias the second quantum noise source such that the second quantum noise source generates a second noise;
a first differential amplifier further comprising a first input channel configured to receive the first noise from the first quantum noise source and a second input channel configured to receive the second noise from the second quantum noise source, wherein the differential amplifier uses a difference between the first noise and the second noise to generate a first amplified analog signal for output; and
an analog-to-digital converter (ADC) device wherein the ADC device is configured to convert an amplified analog signal to the quantum random number stream and output the quantum random number stream.

2. The system of claim 1, wherein at least one of the first quantum noise source or the second quantum noise source comprise a metal-oxide semiconductor field-effect transistor, a junction field-effect transistor, or a tunnel diode.

3. The system of claim 1, wherein the first quantum noise source and the second quantum noise source comprise a same device.

4. The system of claim 1, wherein the first quantum noise source and the second quantum noise source comprise different devices.

5. The system of claim 1, wherein a corrective feedback signal is generated at least in part based on the amplified analog signal and provided to at least one of the differential amplifier, the first bias device, or the second bias device.

6. The system of claim 5, wherein the corrective feedback signal is generated by at least one of an analog accumulator or an analog integrator.

7. The system of claim 1, further comprising:
a third quantum noise source;
a third bias device, configured to bias the third quantum noise source such that the third quantum noise source generates a third noise;
a fourth quantum noise source;
a fourth bias device, configured to bias the fourth quantum noise source such that the fourth quantum noise source generates a fourth noise;
a second amplifier comprising a third input channel configured to receive the third noise from the third quantum noise source and a fourth input channel configured to receive the fourth noise from the fourth quantum noise source, wherein the differential amplifier uses a difference between the third noise and the fourth noise to generate a second amplified analog signal for output; and
a third differential amplifier wherein the third differential amplifier receives the first amplified analog signal and the second amplified analog signal and combines the first amplified analog signal and the second amplified analog signal to generate a combined analog signal for output.

8. The system of claim 7, wherein the combined analog signal is the amplified analog signal, and the ADC device is configured to convert the amplified analog signal to the quantum random number stream and outputs the quantum random number stream.

9. The system of claim 1, wherein a portion of the quantum random number stream is used to generate a quantum random number.

10. The system of claim 9, wherein the quantum random number is accessed by a field programmable gate array configured to modify the quantum random number by at least one of a hash function or a folding technique prior to being output for a user device.

11. A method of generating a quantum random number, the method comprising:
providing, by a first noise source, a first noise to an amplifier;
providing, by a second noise source, a second noise to the amplifier;
combining, by the amplifier, the first noise and the second noise to generate an amplified analog signal for output;
converting, by an analog-to-digital converter (ADC) device, the amplified analog signal into a quantum random number stream; and
outputting, by the ADC device, the quantum random number stream.

12. The method of claim 11, further comprising:
providing, by a first bias device, a first bias to the first noise source such that the first noise source generates the first noise; and
providing, by a second bias device, a second bias to the second noise source such that the second noise source generates the second noise.

13. The method of claim 12, wherein the first bias and the second bias provide a voltage bias or a current bias to the first noise source and the second noise source, respectively.

14. The method of claim 12, wherein the first bias provides a voltage bias to the first noise source and the second bias provides a current bias to the second noise source.

15. The method of claim 12, further comprising:
providing a corrective feedback signal to at least one of the first bias device or the second bias device.

16. The method of claim 11, further comprising:
sampling a portion of the quantum random number stream to generate a quantum random number; and
providing the quantum random number to a user device.

17. A system for generating a quantum random number stream, the system comprising:
a first quantum noise source;
a first bias device, configured to bias the first quantum noise source such that the first quantum noise source generates a first noise;
a second quantum noise source;
a second bias device, configured to bias the second quantum noise source such that the second quantum noise source generates a second noise;
a first differential buffer further comprising a first input channel configured to receive the first noise from the first quantum noise source a second input channel configured to receive a first corrective feedback signal, wherein the first differential buffer combines the first noise and the first corrective feedback signal to generate a first corrected noise;
a second differential buffer further comprising a third input channel configured to receive the second noise from the second quantum noise source and a fourth input channel configured to receive a second corrective feedback signal wherein the second differential buffer combines the second noise and the second corrective feedback signal to generate a second corrected noise;
a differential amplifier that uses a difference between the first corrected noise and the second corrected noise to generate an amplified analog signal for output; and
an analog-to-digital converter (ADC) device wherein the ADC device is configured to convert the amplified analog signal to a quantum random number stream and output the quantum random number stream.

18. The system of claim 17, wherein at least one of the first quantum noise source or the second quantum noise source comprise a metal-oxide semiconductor field-effect transistor, a junction field-effect transistor, or a tunnel diode.

19. The system of claim 17, wherein the first corrective feedback signal and the second corrective feedback signal are the same corrective feedback signal.

20. The system of claim 17, wherein the first corrective feedback signal and the second corrective feedback signal are generated by at least one of an analog accumulator or an analog integrator.
